(19) United States
(12) Patent Application Publication
(10) Pub. No.: US 2025/0309114 A1
(43) Pub. Date: Oct. 2, 2025

(54) INTEGRATED CIRCUIT PACKAGE DEVICE WITH A POWER DELIVERY SUBSTRATE

(71) Applicant: Advanced Micro Devices, Inc., Santa Clara, CA (US)

(72) Inventors: Ahmed Mohamed ABOU-ALFOTOUH, Santa Clara, CA (US); Shardul Suresh ADKAR, Austin, TX (US)

(21) Appl. No.: 18/619,090

(22) Filed: Mar. 27, 2024

(51) Int. Cl. H01L 23/528; H01L 23/495; H01L 23/498; H01L 23/522

(52) U.S. Cl. CPC H01L 23/5286; H01L 23/49589; H01L 23/49816; H01L 23/5226; H01L 23/5283

(57) ABSTRACT

A integrated circuit (IC) package device includes a first substrate, an IC device mounted to a first surface of the first substrate, a second substrate, and first power delivery circuitry. The second substrate is mounted to a second surface of the first substrate. The first surface is opposite the second surface. The second substrate includes a decoupling capacitor. The first power delivery circuitry is mounted to the second substrate and coupled to the IC device through the second substrate and the first substrate.

### TECHNICAL FIELD

Examples of the present disclosure generally relate to power delivery within an integrated circuit (IC) package device, and more particularly to providing power to an IC device of an IC package device via a secondary substrate coupled with a primary substrate having a the IC device mounted thereto.

### BACKGROUND

A package device includes an integrated circuit (IC) device, support circuitry, and power delivery circuitry. The IC device, the support circuitry, and the power delivery circuitry are mounted to the same side (surface) of a substrate. The substrate includes a high density interconnect that provides signal integrity of data signals communicated between the IC device and the support circuitry, and integrity of power signals communicated between the IC device and the power delivery circuitry. The high density interconnect provides an increased wiring density, thinner spaces, and smaller vias per unity area as compared to other types of substrates. The vias and metal layers of the high density interconnect are used to connect the IC device with the support circuitry, and the power delivery circuitry.

### SUMMARY

In one example, a package device includes a first substrate, an integrated circuit (IC) device mounted to a first surface of the first substrate, a second substrate, and first power delivery circuitry. The second substrate is mounted to a second surface of the first substrate. The first surface is opposite the second surface. The second substrate includes a decoupling capacitor. The first power delivery circuitry is mounted to the second substrate and coupled to the IC device through the second substrate and the first substrate.

In one example, an IC system includes a package device and first support summary. The package device includes a first substrate, an IC device mounted to a first surface of the first substrate, a second substrate, and first power delivery circuitry. The second substrate is mounted to a second surface of the first substrate. The first surface is opposite the second surface. The second substrate includes a decoupling capacitor. The first power delivery circuitry is mounted to the second substrate and coupled to the IC device through the second substrate and the first substrate. The first support circuitry is mounted to the first surface of the first substrate and electrically connected to the IC device. The first support circuitry is configured to receive data signals from the IC device.

In one example, a method of forming a package device includes mounting a power delivery circuitry to a first surface of a first substrate, and providing a decoupling capacitor to the first substrate. Further, the method includes mounting a second surface of the first substrate to a first surface of a second substrate. An integrated circuit device is mounted to a second side of the second substrate. The IC device is coupled to the power delivery circuitry through the first substrate and the second substrate.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A illustrates a diagram of a package device.

FIG. 1B illustrates a diagram of a package device.

FIG. 1C illustrates a diagram of a package device.

FIG. 1D illustrates a diagram of a package device.

FIG. 2 illustrates a diagram a portion of a package device.

FIG. 3 illustrates a diagram a portion of a package device.

FIG. 4 illustrates a diagram of a package device.

FIG. 5 illustrates connectors on a bottom surface of an integrated circuit device.

FIG. 6 illustrates a flowchart of a method for forming a package device.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Package devices include multiple components mounted to one or more substrates. For example, package device may include an integrated circuit (IC) device, support circuitry, and power delivery circuitry mounted to the one or more substrates. Vias and metal layers within the substrate or substrates are used to couple the IC device with the support circuitry and the power delivery circuitry. In one example, the vias and metal layers are formed within a high density interconnect within the corresponding substrate or substrates.

In one example, the IC device, support circuitry, and power delivery circuitries are mounted to a first side of a substrate through vias and metal layers within the substrate. Such a configuration limits the area on the substrate that is useable to mount power delivery circuitries and the area within the substrate that is used route power signal lines from the power delivery circuitries to the IC device and data signals from the support circuitry components to the IC device. Accordingly, the amount of power that is deliverable from the power delivery circuitries to the IC device is limited. In some instances, to support the increased power demands of IC devices, the layer count within the substrate is increased. However, increasing the layer count within the substrate increases the manufacturing cost of the substrate and the manufacturing complexity of the substrate.

In one more example, a package device may be referred to as an accelerator device. An accelerator device functions in conjunction with a central processing unit (CPU) to offload tasks from the CPU. The accelerator device may include specialized circuitry for performing the offloaded tasks. For example, the accelerator device may be a graphics processing unit (GPU) that performs image processing, video processing, and/or other parallel computing tasks. In other examples, other types of accelerator devices (e.g., artificial intelligence accelerator devices, cryptographic accelerator cards, and/or vector accelerator cards, among others) may be used. In one or more computing systems, multiple accelerator devices are used to offload tasks from a CPU. The accelerator devices may the same type or include different types of accelerator devices. In such a computing system, due to the number of accelerator cards, the space available to include the accelerator cards within computing system is limited. Accordingly, the density of the accelerator cards is increased, decreasing the size of the accelerator cards, and allowing more accelerator cards to be included within a computing system. In one example, when the density of an accelerator card (or package device) is increased (e.g., the size of an accelerator card is decreased), the interference on the data signals from the power delivery circuitries is increased. Accordingly, decreasing the interference due to power delivery allows for a smaller (e.g., more dense) accelerator device to be manufactured, increasing the number of accelerator cards that can be included within a smaller area within a computing system, decreasing the manufacturing cost of the computing system.

The package device described herein includes a secondary substrate that is mounted to a primary substrate. The IC device is mounted to the primary substrate and the power delivery circuitries are mounted to the secondary substrate. Connectors are used to mount the IC device to the primary substrate and to mount the secondary substrate to the primary substrate. The connectors are surface mounted connectors. For example, the connectors may be solder balls (e.g., ball grid array (BGA) connectors, among others). The connectors on either side of the primary substrate are connected to each other through vias within the primary substrate. The use of a primary substrate and a secondary substrate to connect power delivery circuitries with an IC device increases the power density that can be achieved as the power path resistance between the power delivery circuitries and the IC device is reduced. Further, mounting the power delivery circuitries to a second substrate, which is mounted to the primary substrate, reduces the number of metal layers within the primary substrate used to route power signals. Accordingly, interference within the data signals communicated between the IC device and the support circuitry components is reduced, improving the performance of the data signals. The use of a primary substrate and a secondary substrate as disclosed above further reduces the number of layers of the primary substrate as the secondary substrate is used in the routing of the power signals. Routing the power signals within the secondary substrate reduces the metal layers within the primary substrate that are used to route the power signals, allowing the use of primary substrate with a reduced number of layers. Accordingly, the manufacturing cost of the primary substrate is reduced, reducing the manufacturing cost of the corresponding package device. In one or more examples, the use of a primary substrate and a secondary substrate as disclosed above further alleviates thermal challenges within the primary substrate as the power signal routing within the primary substrate is reduced.

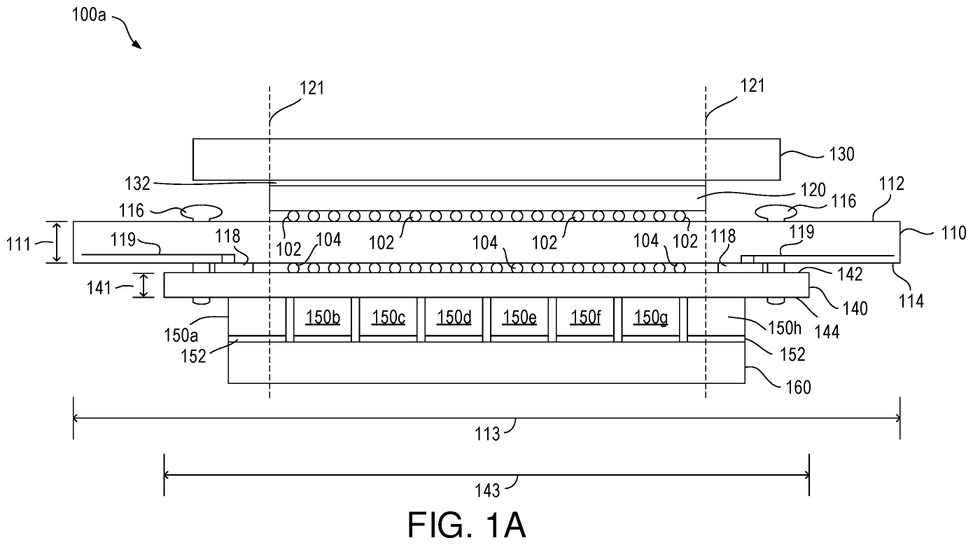

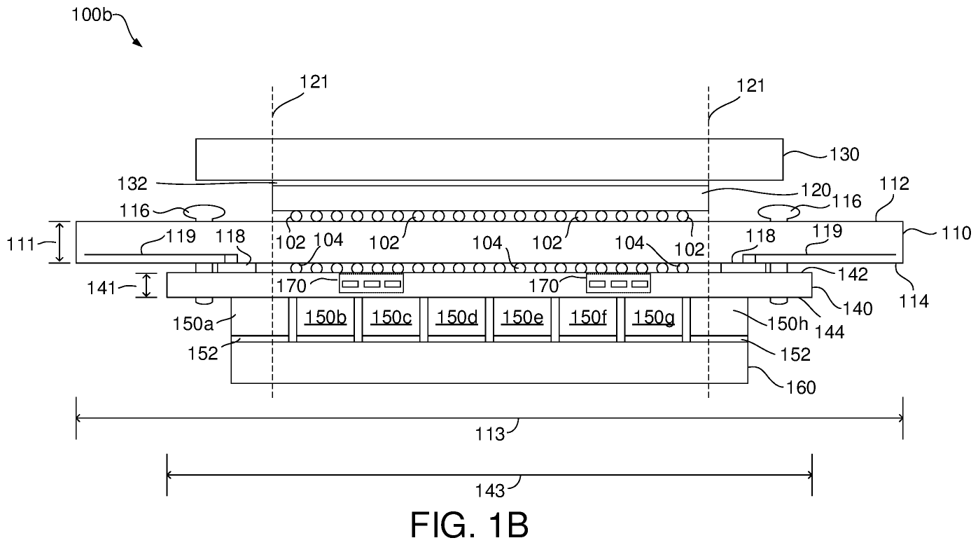

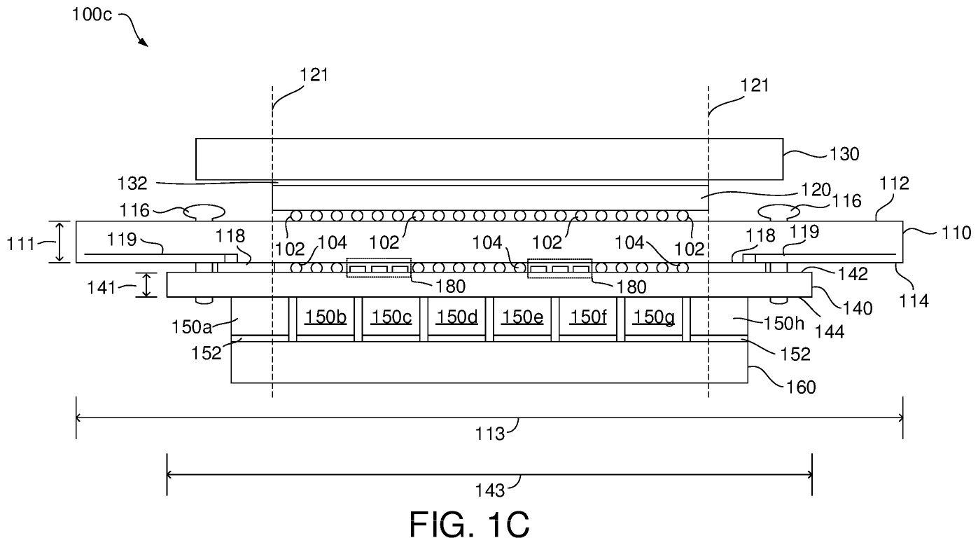

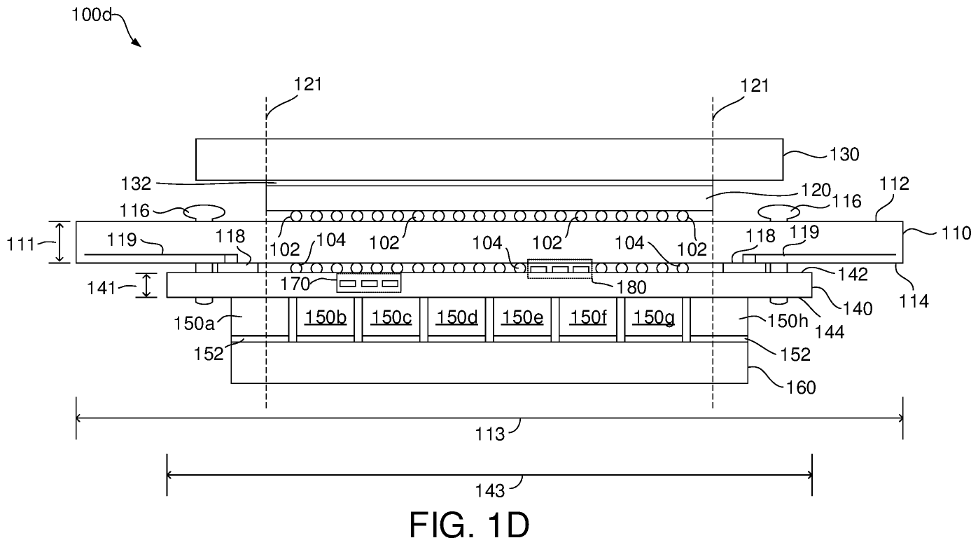

The package device described herein additionally, or alternatively, includes decoupling capacitors disposed within the secondary substrate and/or disposed on the secondary substrate. Such a configuration reduces the distance between the coupling capacitors and the IC device, mitigating noise within the corresponding power delivery network (e.g., the power delivery circuitries, wires, and connectors), improving the high frequency transient response of the power delivery circuitries. Further, the package device described additionally, or alternatively, includes the intermediate bus voltage connectors outside the perimeter of the IC device disposed on the primary substrate. Placing the intermediate bus voltage connectors outside the perimeter of the IC device allows for a distance between the wires coupling the power delivery circuitries mounted on the secondary substrate with the power supply devices and the wires used to communicate data signals to be increased, mitigating power supply noise within the data signals. FIG. 1A illustrates a package device 100a, according to one or more examples. In one example, a package device may be referred to as IC system. The package device 100a includes a substrate 110, an IC device 120, a heatsink 130, a substrate 140, power delivery circuitries 150, and a heatsink 160. In other examples, the package device 100a may include other elements not illustrated in FIG. 1A. For example, the package device 100a may include one or more support circuitries and/or one or more power supply devices, among others. In one example, the package device 100a may be referred to as an accelerator device as described above. In one or more examples multiple package devices 100a are included within the same computing system.

The substrate 110 is a primary substrate, main substrate, or a package substrate. In one example, the substrate 110 is a printed circuit board (PCB). The substrate 110 includes one or more metal layers and/or vias that are used to route signals (e.g., data signals and/or power signals) between devices connected to the substrate 110. The substrate 110 has a height 111 and a width 113. Further, the substrate 110 includes surface 112 and the surface 114 that are opposite each other.

The IC device 120 is mounted to surface (side) 112 of the substrate 110 through the connectors (e.g., connecting elements) 102. The IC device 120 is a processing device. For example, the IC device 120 is a GPU package device, a CPU package device, or another processing device package device, among others.

In one example, the IC device 120 is a package device that includes one or more IC dies (or chips). The one or more IC dies are interconnected with each other. For example, the IC device 120 may include two or more IC dies that are vertically stacked (e.g., mounted or disposed) on each other to form a three dimensional chip stack. The vertically stacked IC dies may be mounted to an interposer (or bridge die) that is mounted to the substrate 110. In one example, the IC device 120 includes two or more IC dies that are horizontally mounted with reference to each other on an interposer (bridge die), which is mounted to the substrate 110 or mounted to the substrate 110 via another substrate. In one or more examples, the IC device 120 includes a combination of vertically stacked and horizontally mounted IC dies, and corresponding interposers and/or substrates.

In one example, the IC device 120 is a package device that includes one or more IC dies that function as a processing device (or devices) and one or more IC dies that function as a memory device (or devices). The memory devices may be high bandwidth memory (HBM) devices. The memory device IC dies are vertically stack on each other and mounted to an interposer (or bridge die) of the IC device 120. A processing IC die (or dies) is mounted to a substrate of the IC device 120, to which the interposer is mounted. The substrate is mounted to the substrate 110 forming the IC device 120.

The connectors 102 are disposed on the surface 112 and couple the IC device 120 with the substrate 110. The connectors 102 physical and/or electrically connect the IC device 120 with the substrate 110. For example, the connectors 102 couple (or connect) input/output pins on the IC device 120 with vias and/or metal layers within the substrate 110. The connectors 102 are solder balls or another type of surface mounted packaging element. In one example, the connectors 102 are BGA connectors.

The substrate 140 is a secondary substrate, a daughter board, or a backside power distribution board (PDB). The substrate 140 includes metal layers and/or vias that are used to electrically connect the power supply circuitries with the connectors 104. The substrate 140 is coupled (e.g. physically and electrically connected) to the surface 114 of the substrate 110.

In one example, the substrate 140 includes less metal layers than the substrate 110. The substrate 140 has a height 141 and a width 143. In one example, the height 141 is less than the height 111 of the substrate 110, and/or the width 143 is less than the width 113 of the substrate 110. In one or more examples, the substrate 140 does not include a high density interconnect with a hybrid stackup, while the substrate 110 includes a high density interconnect with a hybrid stackup. In one example, the substrate 140 is manufactured from less complex manufacturing process, a less costly material, and/or a cheaper manufacturing process than that of the substrate 110. For example, the substrate 140 is manufactured from FR4, while the substrate 110 is manufactured from a more expensive and complex manufacturing process and/or material (e.g., polytetrafluoroethylene (PTFE), or another similar type material). Accordingly, using the substrate 140 reduces the manufacturing cost of the package device 100a.

The connectors 104 are disposed on the surface 114 of the substrate 110 and the surface 142 of the substrate 140. The connectors 104 couple the substrate 140 with the substrate 110. For example, the connectors 104 physically and/or electrically connect the substrate 140 with the substrate 110. In one example, the connectors 104 couple vias and/or metal layers within the substrate 140 with vias and/or metal layers within the 110. The connectors 104 are solder balls or another type of surface mounted packaging element. In one example, the connectors 104 are BGA connectors.

In one example, the substrate 140 is coupled to the substrate 110 via fasteners 116. The fasteners 116 may be screws, rivets, or bolts, among others.

The power delivery circuitries 150 are disposed on the surface 144 of the substrate 140. The surface 144 is opposite the surface 142. The power delivery circuitries 150 include one or more power delivery circuitries 150. In one example, the power delivery circuitries 150 are voltage regulator circuitries or types of circuitries that are able to convert power from one voltage level to another. In one example, the power delivery circuitries 150a-150h receive power via the connectors (e.g., power supply connectors) 118, and output one or more power signals based on the received power signals. The output power signals have a voltage level different from the received power signals. In one or more examples, at least one power delivery circuitry 150 outputs a power signal having a different voltage level than a power signal output by at least one other power delivery circuitry 150. In one example, the power signals output by the power delivery circuitries 150 are received by the IC device 120 via the substrate 140, the substrate 110, and the connectors 102 and 104.

The connectors 118 include one or more conductive (e.g., metal or another conductive material) pillars. In one example, the conductive pillars are copper. The connectors 118 are coupled to a power supply device or devices via the wires 119 routed within a metal layer or layers of the substrate 110. In one example, the wires 119 are routed a distance away from wires that are used to communicate data signals to mitigate power supply related interference generated within the data signals. In one example, the connectors 118 are disposed outside the perimeter of the IC device 120. The perimeter of the IC device 120 is illustrated as 121. The connectors 118 are disposed such that the connectors 118 are outside the perimeter 121 of the IC device 120, and do not overlap the IC device 120.

In one example, the power delivery circuitries 150 are connected to the IC device 120 through the vias and/or metal layers within the substrate 140, the connectors 104, the vias and/or metal layers within the substrate 110, and the connectors 102. A power delivery circuitry 150 is connected to one or more of the connectors 104 and to one or more of the connectors 102.

In one example, mounting the power delivery circuitries 150 on the substrate 140 as described above, allows for a greater number of input and output capacitors of the power delivery circuitries 150 to be used, mitigating the input and output noise of the power delivery circuitries 150. Further, the configuration as described above reduces the power path resistance between the power delivery circuitries 150 and the IC device 120 by at least fifty percent as compared to mounting the power delivery circuitries 150 directly on the substrate 110.

The heatsink 130 is disposed on the IC device 120. In one example, a thermal interface material 132 is disposed between the IC device 120 and the heatsink 130. The heatsink 160 is disposed on the power delivery circuitries 150. In one example, a thermal interface material 152 is disposed between the power delivery circuitries 150 and the heatsink 160. The thermal interface material 132 and the heatsink 130 function a heat exchanger to transfer heat from the IC device 120. Further, the thermal interface material 152 and the heatsink 160 function as a heat exchanger to transfer heat from the power delivery circuitries 150.

FIG. 1B illustrates a package device 100b, according to one or more examples. The package device 100b is configured similar to the package device 100a of FIG. 1A. For example, the package device 100b includes the substrate 110, the IC device 120, the heatsink 130, the substrate 140, the power delivery circuitries 150, and the heatsink 160. Further, the package device 100b includes decoupling capacitors 170 disposed within the substrate 140.

In one example, the decoupling capacitors 170 include N decoupling capacitors. N is one or more. The decoupling capacitors 170 are formed within one or more metal layers of the substrate 140. The substrate 140 includes one or more metal (or another conductive material) layers and one or more insulating layers. The metal layers and insulating layers are alternatively disposed on each other, forming the substrate 140. The decoupling capacitors 170 may be disposed within a single metal layer of the substrate 140, or in multiple metal layers of the substrate 140. In one example, a first one or more decoupling capacitors 170 are formed in a first metal layer of the substrate 140 and a second one or more decoupling capacitors 170 are formed in a second metal layer different than the first metal layer. The decoupling capacitors 170 may be formed in a metal layer of the substrate 140 in which a connection between at least one of the power delivery circuitries 150 and at least one of the connectors 104 is routed. In another example, the metal layer or layers of the substrate 140 used to form the decoupling capacitors 170 is free from other routings. While the example of FIG. 1B illustrates decoupling capacitors 170 formed in two different locations within the substrate 140, in other examples, the decoupling capacitors are formed in other locations of the substrate 140.

The decoupling capacitors 170 are connected to the routing (e.g., vias and traces) between the power delivery circuitries 150 and the connectors 104. The decoupling capacitors 170 improve the power delivery network (PDN) noise.

FIG. 1C illustrates a package device 100c, according to one or more examples. The package device 100c is configured similar to the package device 100a of FIG. 1A. For example, the package device 100c includes the substrate 110, the IC device 120, the heatsink 130, the substrate 140, the power delivery circuitries 150, and the heatsink 160. Further, the package device 100b includes decoupling capacitors 180 mounted to the substrate 140.

In one example, the decoupling capacitors 180 include M decoupling capacitors. M is one or more. The decoupling capacitors 180 are surface mounted to the substrate 140. In one example, the decoupling capacitors 180 are disposed between two or more of the connectors 104. The decoupling capacitors 180 are disposed in a space devoid of the connectors 104. In one example, the decoupling capacitors 180 are formed within the perimeter of the IC device 120 and the outside perimeter of the power delivery circuitries 150. While the example of FIG. 1C illustrates decoupling capacitors 180 formed in two different locations on the substrate 140, in other examples, the decoupling capacitors 180 are formed in other locations on the substrate 140 within areas devoid of the connectors 104.

FIG. 1D illustrates a package device 100d, according to one or more examples. The package device 100d is configured similar to the package device 100a of FIG. 1A. For example, the package device 100c includes the substrate 110, the IC device 120, the heatsink 130, the substrate 140, the power delivery circuitries 150, and the heatsink 160. Further, the package device 100d includes the decoupling capacitors 170 formed within the substrate 140 and the decoupling capacitors 180 mounted to the substrate 140. The package device 100d includes one or more decoupling capacitors 170 and one or more decoupling capacitors 180. The location of the decoupling capacitors 170 and/or the decoupling capacitors 180 may differ from that illustrated in FIG. 1D. Further, the package device 100d includes more decoupling capacitors 170 than decoupling capacitors 180, more decoupling capacitors 180 than the decoupling capacitors 170, or the same amount of decoupling capacitors 170 and 180.

In one or more examples, using the decoupling capacitors 170 and/or the decoupling capacitors 180 decreases the complexity and cost of manufacturing the substrate 110 and the corresponding package device. For example, the decoupling capacitors 170 are formed within the substrate 140, which is mounted to the substrate 110. As the substrate 140 is a lower cost substrate as compare to the substrate 110, cost of forming the decoupling capacitors 170 within the substrate 140 is less than forming the decoupling capacitors 170 in the substrate 110, decreasing the cost of the corresponding package device. In one example, the decoupling capacitors 180 are surface mounted to the substrate 140, before the substrate 140 is mounted to the substrate 110. Surface mounting the decoupling capacitors 180 to the substrate 140, reducing the manufacturing costs of the corresponding package device as processing the substrate 140 is at a lower cost than processing the more complex substrate 110.

In one or more examples, as the decoupling capacitors 170 and the decoupling capacitors 180 are located in close proximity to the power delivery circuitries 150 and corresponding wires and connectors 104, a reduced number of decoupling capacitors 170 and/or the decoupling capacitors 180 can be used as compared to package devices that include the decoupling capacitors on and/or with the substrate 110. Accordingly, a package device including the decoupling capacitors 170 and/or the decoupling capacitors 180 has a lower manufacturing cost.

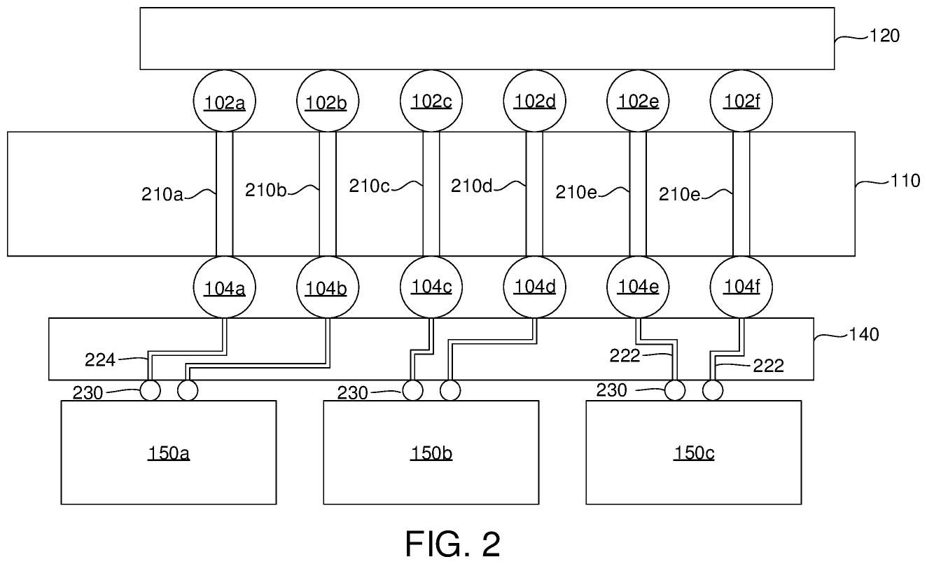

FIG. 2 illustrates a portion of the package device 100a, according to one or more examples. As is illustrated in FIG. 2, the connectors 104 are coupled with the connectors 102 through a corresponding via 210 in the substrate 110. For example, the connector 102a is coupled with the connector 104a through the via 210a, the connector 102b is coupled with the connector 104b through the via 210b, the connector 102c is coupled with the connector 104c through the via 210c, the connector 102d is coupled with the connector 104d through the via 210d, the connector 102e is coupled with the connector 104e through the via 210e, and the connector 102f is coupled with the connector 104f through the via 210f. In the example of FIG. 2, one or more of the connectors 104 is vertically aligned with a respective one of the connectors 102, such that the vertically aligned connectors can be coupled through a via and without the use of metal layers within the substrate 110. Accordingly, the power path resistance between the power delivery circuitries 150 and the IC device 120 is reduced, increasing the amount of power that can be delivered to the IC device, and decreasing interference that may occur on the data signals communicated to and from the IC device 120.

In one example, the connectors 104 are disposed such that the connectors 104 that output power supply signals are aligned with (e.g., correspond to or match the location of) power supply pins of the IC device 120. Further, the connectors 104 are disposed such that the connectors 104 that output a ground voltage (e.g., a reference voltage) are aligned with (e.g., correspond to or match the location of) ground voltage pins of the IC device 120. In one example, the connectors 102 and 104 are BGA connectors. The BGAs are disposed to correspond to the power supply and ground voltage pins of the IC device 120.

As is further is illustrated in FIG. 2, the power delivery circuitries 150 are connected to vias and metal lines 224 within the substrate 140. In one example, the power delivery circuitries 150 are connected to the vias and metal lines 224 through connectors 230. The connectors 230 are solder balls. In one example, the connectors 230 are C4 bumps. In one example, vias are used to connect a first one of the connectors 230 with one of the connectors 104, and vias and metal layers are used to connect a second one of the connectors 230 with one of the connectors 104.

In one example, one or more of the power delivery circuitries 150 are coupled to connectors 230, and to connectors 104. The number of connectors 230 and/or 104 connected to each power delivery circuitry 150 may be the same or differ between two or more of the power delivery circuitries 150.

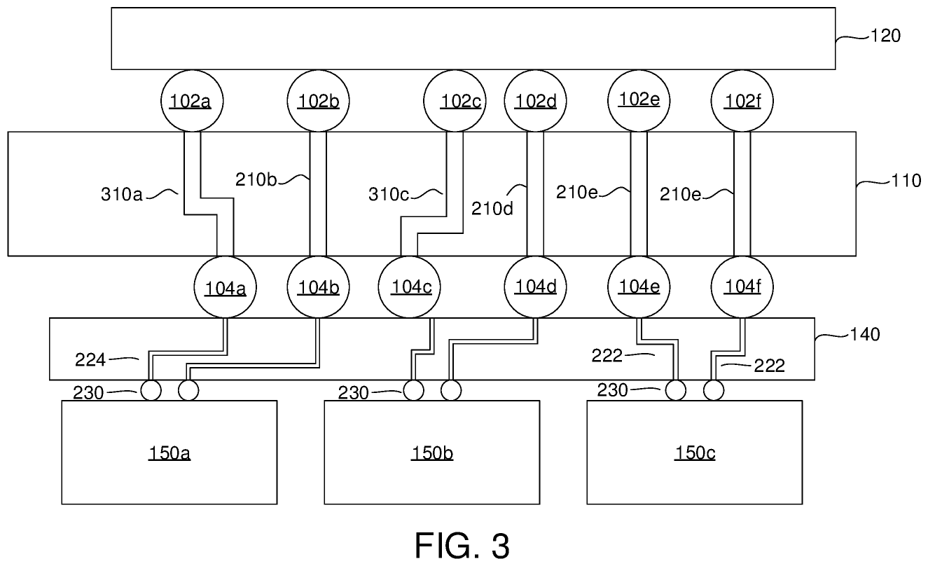

FIG. 3 illustrates a portion of the package device 100a, according to one or more examples. The example of FIG. 3 is similar to example 2. In the example of FIG. 3, one or more of the connectors 104 is connected to one or more of the connectors 102 through vias and metal layers within the substrate 110. For example, the connector 104a is connected to the connector 102a through vias and metal layers 310a within the substrate 110. Further, the connector 104c is connected to the connector 102c through vias and metal layers 310c within the substrate 110. In one example, at least one of the connectors 104 is directly coupled to a connector 102 through a via within the substrate 110 without the use of metal layers within the substrate 110. For example, the connector 104b is directly coupled with the connector 102b through the via 210b without the use of metal layers within the substrate 110, the connector 104d is directly coupled with the connector 102d through the via 210d without the use of metal layers within the substrate 110, the connector 104e is directly coupled with the connector 102e through the via 210e without the use of metal layers within the substrate 110, and the connector 104f is directly coupled with the connector 102f through the via 210f without the use of metal layers within the substrate 110. Directly coupling a connector 104 with a connector 102 though the use of a via and without the use of metal layers may be referred to as vertically coupling the connectors 102 and 104. In other examples, each of the connectors 102 is connected with a respective one of the connectors 104 through vias and metal layers within the substrate 110. Coupling a connector 104 with a connector 102 though the use of a via and a metal layer may be referred to as vertically and horizontally coupling the connectors 102 and 104.

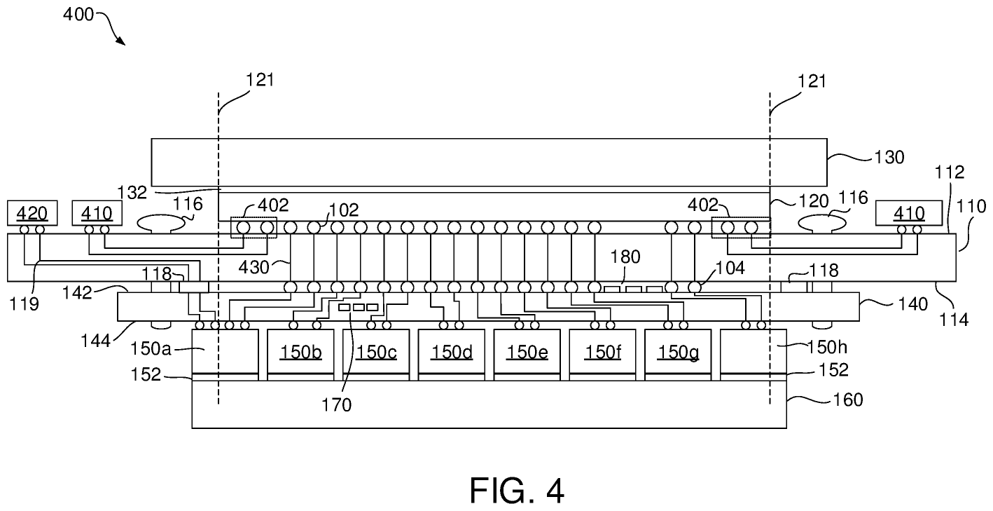

FIG. 4 illustrates a package device 400, according to one or more examples. The package device 400 includes the substrate 110, the IC device 120, the heatsink 130, the substrate 140, the power delivery circuitries 150, and the heatsink 160. The package device 400 may further include one or more decoupling capacitor 170 and/or one or more decoupling capacitor 180. As is disclosed above, the connectors 102 electrically connect the substrate 110 with the IC device 120. Further, the connectors 104 electrically connect the substrate 110 with the substrate 140. The connectors 102 are coupled to the connectors 104 via the traces and/or vias within the substrate 110. For example, the connectors 102 are coupled to the connectors 104 as described with regard to FIG. 2 or FIG. 3.

The package device 400 further includes support circuitries 410 and power supply circuitries 420. The support circuitries 410 include one or more memory circuitries, one or more input/output circuitries, one or more processing circuitries, and/or one or more interface circuitries, among others. The support circuitries 410 communicate data signals to and from the IC device 120 via traces and/or vias within the substrate 110, and the connectors 402. In one example, the support circuitries 410 perform one or more functions (or operations) on the data received from the IC device 120 in support of the operation of the IC device 120. A support circuitry 410 is connected to one or more of the connectors 402. The power supply circuitries 420 provide reference power signals to the power delivery circuitries 150 via the connectors 118 and wires 119.

In one example, one or more of the power supply circuitries 420 is mounted on surface 112 of the substrate 110. In such an example, at least one power supply circuitry 420 is mounted to the surface 112 and at least one power delivery circuitry 150 is mounted to the surface 144 of the substrate 140. Further, in one or more examples, a circuit device other than a power delivery circuitry 150 may be mounted to the surface 144 of the substrate 140, and is coupled to the IC device 120 as is described above with regard to power delivery circuitries 150. In one example, one or more support circuitry 410 is mounted to the surface 144 and is coupled to the IC device 120 through vias and metal layers within the substrate 140, the connectors 104, the vias and metal layers 430, and the connectors 102. In another example, one or more of the power supply circuitries 420 may be located external to the substrate 110, and coupled to the wires 119 via one or more connecters mounted on the substrate 110.

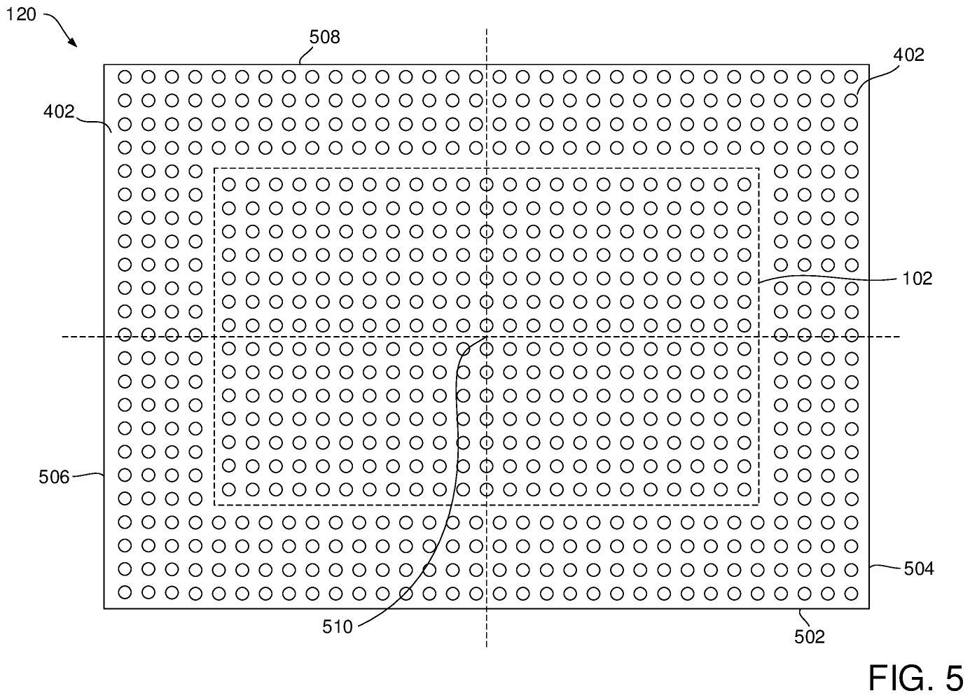

In one example, the connectors 402 are disposed along the perimeter of the IC device 120, and the connectors 102 are disposed proximate the center of the IC device 120. FIG. 5 illustrates a bottom surface of the IC device 120 on which the connectors 102 and 402 are disposed. As is illustrated in FIG. 5, the connectors 402 are disposed along the perimeter of the bottom surface of the IC device 120, and the connectors 102 are disposed proximate the center of the IC device 120. The connectors 402 are disposed closer to the edges 502, 504, 506, and 508 of the IC device 120 than the connectors 102. Further, the connectors 102 are disposed closer to the center 510 of the IC device 120 than the connectors 402.

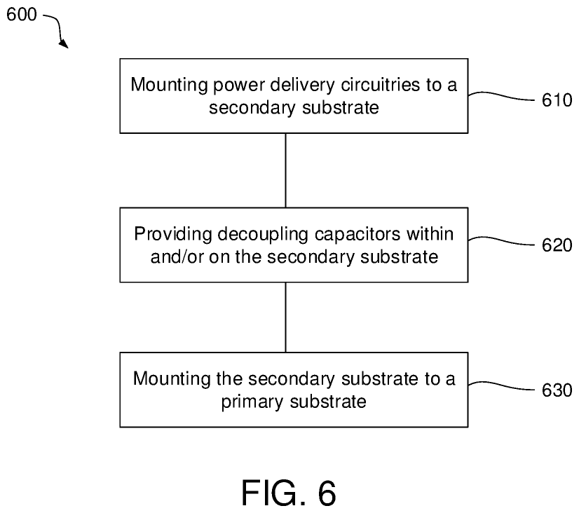

FIG. 6 illustrates a flowchart of a method 600 for forming a package device (e.g., the package device 100a-100D or 400). At 610 of the method 600, power delivery circuitries are mounted to a secondary substrate. For example, with reference to FIG. 4, one or more of the power delivery circuitries 150 is mounted to the surface 144 of the substrate 140. Connectors formed on the power delivery circuitries 150 and/or on the surface 144 of the substrate 140 are used to mount the power delivery circuitries 150. In one example, a reflow process is used to mount the power delivery circuitries 150 to the surface 144 of the substrate 140 via the connectors. The connectors are coupled to routing within the substrate 140 that connects the power delivery circuitries 150 with the connectors 104.

At 620 of the method 600, decoupling capacitors are provided within and/or on the secondary substrate. For example, with regard to FIG. 4, the decoupling capacitors 170 are formed within metal layers of the substrate 140 and/or the decoupling capacitors are formed on the surface 142 of the substrate 140.

At 630 of the method 600, the secondary substrate is mounted to a primary substrate. For example with reference to FIG. 4, the substrate 140 is mounted to the substrate 110. The connectors 104 are reflowed to mount the substrate 140 to the substrate 110. In one example, the connectors 104 are surface mounted to the surface 142 of the substrate 140, and reflowed to mount the substrate 140 to the substrate 110.

As is described in the method 600, the decoupling capacitors 170 are formed within and/or the decoupling capacitors 180 are mounted to the substrate 140, before the substrate 140 is mounted to the substrate 110. As the substrate 140 is a lower complexity and lower cost substrate than the substrate 110, the manufacturing costs of forming the decoupling capacitors 170 within and/or mounting the decoupling capacitors 180 to the substrate 140 is cheaper than performing similar processes on the substrate 110, decreasing the manufacturing costs of the corresponding package device (e.g., the package device 400 of FIG. 4).

While the foregoing is directed to specific examples, other and further examples may be devised without departing from the basic scope thereof, and the scope thereof is determined by the claims that follow.

What is claimed is:

1. A package device comprising:
a first substrate;
an integrated circuit (IC) device mounted to a first surface of the first substrate;
a second substrate mounted to a second surface of the first substrate, wherein the first surface is opposite the second surface, and wherein the second substrate includes a decoupling capacitor; and
first power delivery circuitry mounted to the second substrate and coupled to the IC device through the second substrate and the first substrate.

2. The package device of claim 1, wherein one or more connectors are mounted to a first surface of the second substrate and are connected to the first power delivery circuitry, and wherein the decoupling capacitor is mounted to the first surface the second substrate.

3. The package device of claim 1, wherein the decoupling capacitor is formed within one or more metal layers of the second substrate.

4. The package device of claim 1 further comprising a first connector mounted to the second substrate and coupled to the first power delivery circuitry, wherein the first connector is mounted outside a perimeter of the IC device.

5. The package device of claim 1, wherein the first power delivery circuitry is mounted to a first surface of the second substrate, and a second surface of the second substrate is mounted to the second surface of the first substrate.

6. The package device of claim 5, wherein first connectors are disposed between the first surface of the first substrate and the IC device, and second connectors are disposed between the second surface of the first substrate and the second surface of the second substrate.

7. The package device of claim 6, wherein a first connector and a second connector of the first connectors are respectively associated with a power supply pin and a ground pin of the IC device, and a third connector and a fourth connector of the second connectors are respectively configured to output a power supply signal and a ground voltage, and wherein the first connector is aligned with the third connector and the second connector is aligned with the fourth connector.

8. The package device of claim 6, wherein a first one of first connectors is coupled to a first one of the second connectors through a first via in the first substrate, and wherein the first power delivery circuitry is coupled to the first one of the second connectors through one or more vias and one or more metal lines within the second substrate.

9. The package device of claim 8, wherein the first one of the first connectors is vertically aligned with the first one of the second connectors.

10. The package device of claim 8 further comprising second power delivery circuitry mounted to the second substrate and coupled to the IC device through the second substrate and the first substrate, wherein a second one of the first connectors is coupled to a second one of the second connectors through a second via in the first substrate, and wherein the second power delivery circuitry is coupled to the second one of the second connectors, and wherein the second one of the first connectors is further coupled to the second one of the second connectors through one or more metal layers within the first substrate.

11. The package device of claim 1, wherein the IC device includes one or more IC dies vertically mounted on each other, wherein the one or more IC die include a high bandwidth memory device.

12. The package device of claim 1, wherein the IC device includes one or more IC dies mounted to an interposer.

13. The package device of claim 1, wherein a first heatsink is mounted to the IC device and a second heatsink is mounted to the first power delivery circuitry.

14. An integrated circuit (IC) system comprising:
a package device comprising:
a first substrate;
an IC device mounted to a first surface of the first substrate;
a second substrate mounted to a second surface of the first substrate, wherein the first surface is opposite the second surface, and wherein the second substrate includes a decoupling capacitor; and
first power delivery circuitry mounted to the second substrate and coupled to the IC device through the second substrate and the first substrate; and
first support circuitry mounted to the first surface of the first substrate and electrically connected to the IC device, wherein the first support circuitry is configured to receive data signals from the IC device.

15. The IC system of claim 14, wherein at least one of:
one or more connectors are mounted to a first surface of the second substrate, and wherein the decoupling capacitor is mounted to the first surface the second substrate, or
the decoupling capacitor is formed within one or more metal layers of the second substrate.

16. The IC system of claim 14, wherein the first power delivery circuitry is mounted to a first surface of the second substrate, and a second surface of the second substrate is mounted to the second surface of the first substrate, wherein first connectors are disposed between the first surface of the first substrate and the IC device, and second connectors are disposed between the second surface of the first substrate and the second surface of the second substrate, and wherein the first one of the first connectors is vertically aligned with the first one of the second connectors.

17. The IC system of claim 16, wherein a first connector and a second connector of first connectors are respectively associated with a power supply pin and a ground pin of the IC device, and a third connector and a fourth connector of the second connectors are respectively configured to output a power supply signal and a ground voltage, and wherein the first connector is aligned with the third connector and the second connector is aligned with the fourth connector.

18. The IC system of claim 14, wherein the IC device includes one or more IC dies vertically mounted on each other, wherein the one or more IC die include a high bandwidth memory device, or wherein the IC device includes one or more IC dies mounted to an interposer.

19. A method of forming a package device, the method comprising:
mounting a power delivery circuitry to a first surface of a first substrate;
providing a decoupling capacitor to the first substrate; and
mounting a second surface of the first substrate to a first surface of a second substrate, wherein an integrated circuit device is mounted to a second side of the second substrate, and wherein the IC device is coupled to the power delivery circuitry through the first substrate and the second substrate.

20. The method of claim 19 further comprising at least one of:
mounting the decoupling capacitor on a second surface of the first substrate; and
forming the decoupling capacitor within a metal layer of the first substrate.
